(19) United States
(12) Patent Application Publication
(10) Pub. No.: US 2015/0138727 A1
(43) Pub. Date: May 21, 2015

(54) CONNECTOR STRUCTURE AND ELECTRONIC APPARATUS USING THE SAME

(71) Applicant: Acer Incorporated, New Taipei City (TW)

(72) Inventor: Hsiu-Pen Lin, New Taipei City (TW)

(73) Assignee: Acer Incorporated, New Taipei City (TW)

(21) Appl. No.: 14/291,012

(22) Filed: May 30, 2014

(30) Foreign Application Priority Data
Nov. 19, 2013 (TW) 102142130

(51) Int. Cl. G06F 1/16; H05K 5/02; H05K 5/00; H01R 13/60

(52) U.S. Cl. CPC G06F 1/1656; H01R 13/60; G06F 1/1626; H05K 5/0247; H05K 5/0026
USPC 361/679.56; 439/571

(57) ABSTRACT

An electronic apparatus including a body, a first connector, and a holder is provided. The body has a slot. The first connector is installed in the slot. The holder is pivoted to an internal wall of the slot to be rotated between a first position and a second position. The holder has a supporting surface. When a second connector is inserted into the slot to connect the first connector, the second connector presses the supporting surface to cause the holder to rotate from the first position to the second position, such that a portion of the second connector is supported on the supporting surface.

### CROSS-REFERENCE TO RELATED APPLICATION

This application claims the priority benefit of Taiwan application serial no. 102142130, filed on Nov. 19, 2013. The entirety of the above-mentioned patent application is hereby incorporated by reference herein and made a part of this specification.

### BACKGROUND OF THE INVENTION

1. Field of the Invention

The invention relates to an electronic apparatus, and more particularly relates to an electronic apparatus having a connector structure.

2. Description of Related Art

As technology advances, various electronic devices, such as laptop computers, tablet computers, and mobile phones, etc., have been developed. Through these electronic devices, the user can send or receive data in real time, which makes them indispensable to the modern life.

Take tablet computer as an example, most of the current tablet computers are equipped with a connector as a transmission medium for electrical connection between the tablet computers and the peripheral equipment. However, as tablet computers are developed to be thinner and lighter, partial structures of the connector may be eliminated to match the appearance of the tablet computers. As a result, when a connector of the peripheral equipment is inserted to the aforementioned connector, the aforementioned connector may not provide adequate support in structure, which causes poor contact between the two connectors and lowers the reliability of the tablet computer.

### SUMMARY OF THE INVENTION

The invention provides a connector structure capable of maintaining a holding force to ensure the support.

The invention provides an electronic apparatus using the connector structure to ensure the support and having favorable reliability.

The connector structure of the invention is adapted for an electronic apparatus which has a slot. The connector structure includes a first connector and a holder. The first connector is disposed in the slot. The holder is pivoted to an internal wall of the slot to be rotated between a first position and a second position. The holder has a supporting surface. When a second connector is inserted into the slot to connect the first connector, the second connector presses the supporting surface to drive the holder to rotate from the first position to the second position, such that a portion of the second connector is supported on the supporting surface.

The electronic apparatus of the invention includes a body, a first connector, and a holder. The body has a slot. The first connector is disposed in the slot. The holder is pivoted to an internal wall of the slot to be rotated between a first position and a second position. The holder has a supporting surface. When a second connector is inserted into the slot to connect the first connector, the second connector presses the supporting surface to drive the holder to rotate from the first position to the second position, such that a portion of the second connector is supported on the supporting surface.

Based on the above, the holder in the connector structure of the invention is pivoted to the internal wall of the slot and is rotatable between two positions. When the second connector is inserted into the slot to connect the first connector, the second connector presses the holder to move from the first position to the second position and rotate outside the slot, such that the second connector is supported on the supporting surface of the holder. Accordingly, the connector structure provides a favorable holding force to ensure the support for the second connector, such that the electronic apparatus using the connector structure has favorable reliability.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a schematic perspective view of an electronic apparatus according to an embodiment of the invention.

FIG. 2 is an enlarged view of a portion A of the electronic apparatus of FIG. 1.

FIG. 3 is an exploded view of the electronic apparatus of FIG. 2.

FIG. 4A to FIG. 4B are schematic views showing motion of a connector structure of FIG. 2.

FIG. 5 is a schematic perspective view of the connector structure of FIG. 4A in a first position.

FIG. 6 is a schematic perspective view of the connector structure of FIG. 4B in a second position.

### DESCRIPTION OF THE EMBODIMENTS

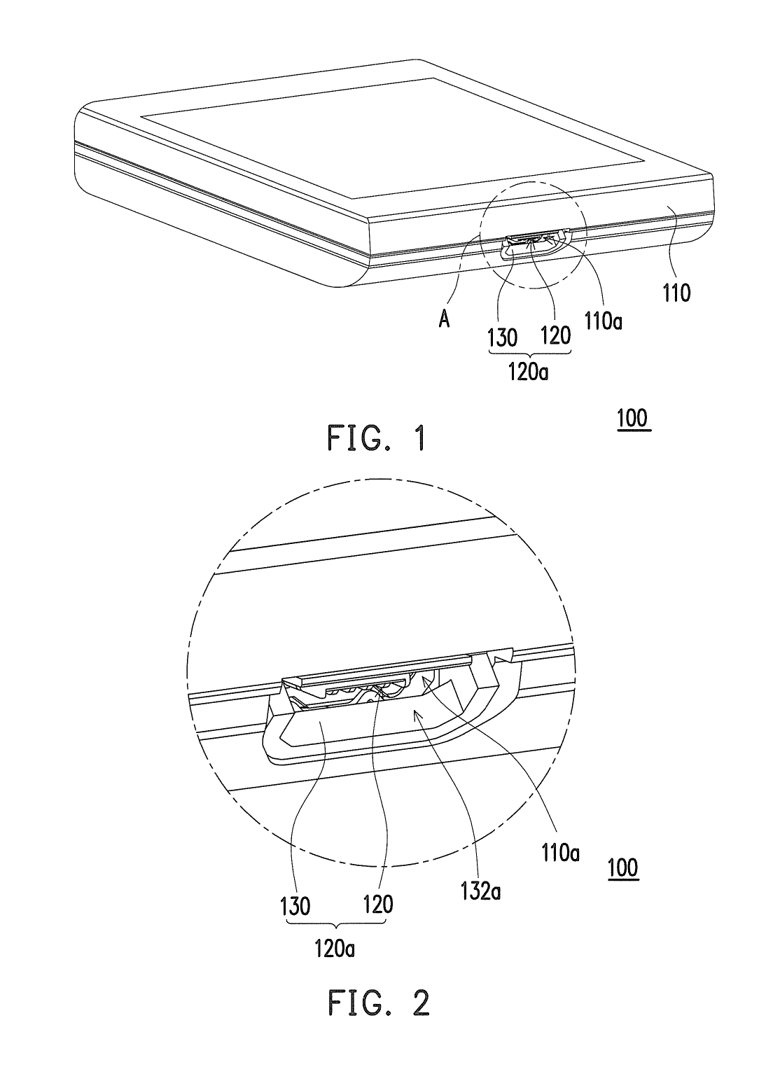

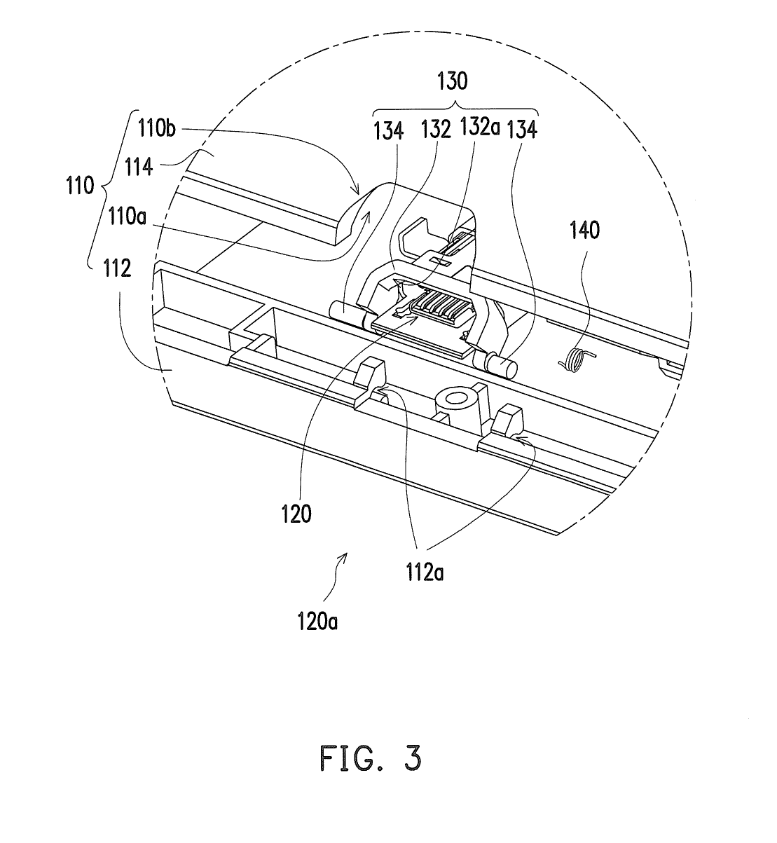

FIG. 1 is a schematic perspective view of an electronic apparatus according to an embodiment of the invention. FIG. 2 is an enlarged view of a portion A of the electronic apparatus of FIG. 1. FIG. 3 is an exploded view of the electronic apparatus of FIG. 2. Referring to FIG. 1, FIG. 2, and FIG. 3, in this embodiment, an electronic apparatus 100 includes a body 110, a first connector 120, and a holder 130. The body 110 has a slot 110a. The first connector 120 is disposed in the slot 110a. It should be noted that, in order to make the figures clear, a perspective of the electronic apparatus 100 in FIG. 3 differs from a perspective of the electronic apparatus 100 in FIG. 2.

Moreover, the body 110 includes an upper case 112 and a lower case 114, wherein the upper case 112 and the lower case 114 each have a gap (not shown). After assembling the upper case 112 and the lower case 114, the gap of the upper case 112 and the gap of the lower case 114 form the slot 110a for receiving the first connector 120. The holder 130 includes a supporting portion 132 and a pair of pivots 134 connected with the supporting portion 132. Moreover, the upper case 112 has a pair of bearings 112a corresponding to the pair of pivots 134, wherein the bearings 112a may be formed by extending an internal structure of the upper case 112. After coordinating the pivots 134 with the bearings 112a, the holder 130 is pivoted inside the body 110 to be rotated between different positions. In another embodiment, the lower case 114 is provided with the pair of bearings 112a to be coordinated with the pair of pivots 134. That is, this disclosure of the invention is not intended to limit the position of the holder pivoted in the body 110, and a proper pivot structure may be disposed in the body 110 according to the user's needs.

Furthermore, the electronic apparatus 100 of this embodiment is an electronic product, such as a tablet computer, a laptop computer, and a mobile phone, etc., and the first connector 120 and the holder 130 form a connector structure 120a. By disposing the connector structure 120a in the aforementioned electronic product, the first connector 120 is properly supported when being detached or inserted, and therefore the electronic product has favorable reliability. Motion of the connector structure 120a is explained hereinafter in detail.

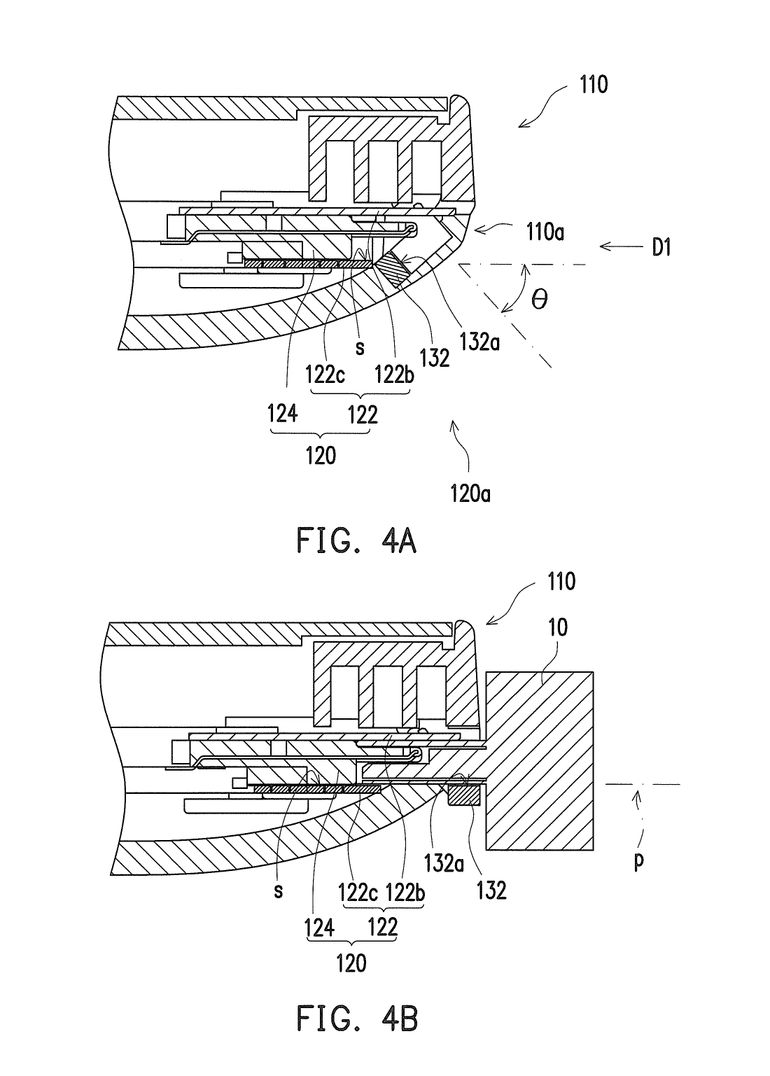

FIG. 4A to FIG. 4B are schematic views showing motion of the connector structure of FIG. 2. With reference to FIG. 2, FIG. 3, and FIG. 4A, the holder 130 of this embodiment has a supporting surface 132a that is disposed on the supporting portion 132. When the holder 130 is in a first position (as shown in FIG. 4A), the supporting surface 132a is located in the slot 110a of the body 110.

With reference to FIG. 2, FIG. 3, and FIG. 4B, when a second connector 10 is inserted into the slot 110a of the body 110 to be connected with the first connector 120, the second connector 10 presses the supporting surface 132a of the holder 130 to drive the holder 130 to rotate and causes the holder 130 to rotate from the first position to the second position (as shown in FIG. 4B), and the supporting surface 132a of the holder 130 is rotated outside the slot 110a of the body 110. Therefore, the supporting surface 132a of the holder 130 is adapted for supporting a portion of the second connector 10.

More specifically, when the holder 130 is rotated outside the slot 110a of the body 110 and located in the second position, the supporting surface 132a of the holder 130 is used for supporting the second connector 10, such that the connector structure 120a provides a favorable holding force for holding the second connector 10 to ensure the support. Hence, when the first connector 120 and the second connector 10 are connected with each other, the second connector 10 is prevented from coming off the first connector 120, and poor contact between the two connectors and failure of electrical connection are avoided. Therefore, the electronic apparatus 100 has better reliability. In addition, when the holder 130 is rotated inside the slot 110a of the body 110 and located in the first position, an outer edge of the holder 130 matches an opening 110b of the slot 110a, such that the shapes of the connector structure 120a and the body 110 are integrated with each other. With this configuration, the electronic apparatus 100 using the connector structure 120a meets the user's demands for higher reliability and thinner size.

Referring to FIG. 3, the connector structure 120a of this embodiment further includes an elastic member 140, such as a torsion spring, for example. The elastic member 140 connects the holder 130 and the bearings 112a of the upper case 112. When the second connector 10 (see FIG. 4B) is detached from the slot 110a of the body 110, an elastic force of the elastic member 140 drives the holder 130 back to the first position, such that the supporting surface 132a of the holder 130 remains in the slot 110a for the first connector 120 and the second connector 10 to be connected again.

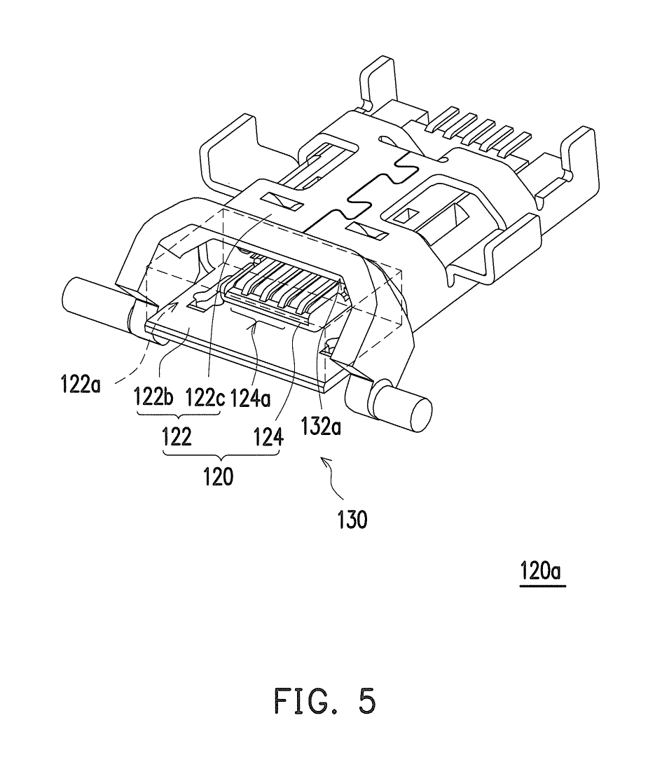

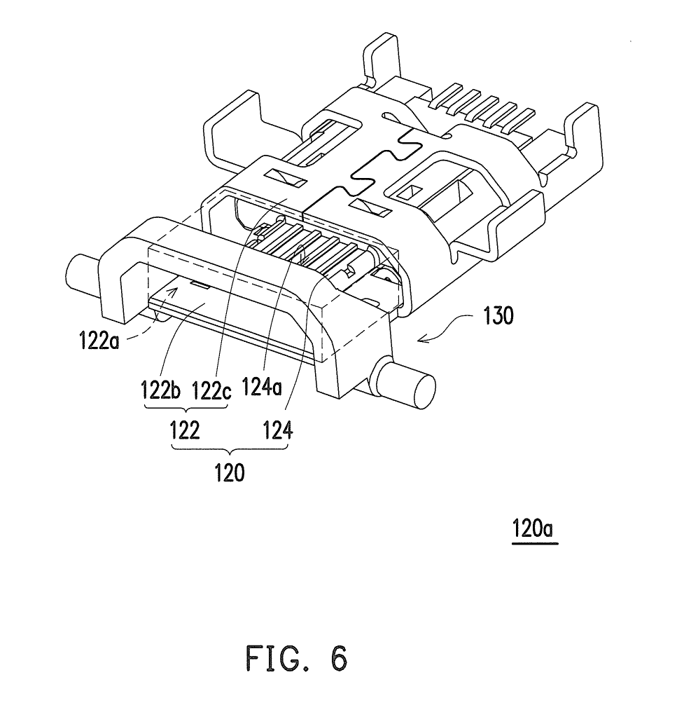

FIG. 5 is a schematic perspective view of the connector structure of FIG. 4A in the first position. FIG. 6 is a schematic perspective view of the connector structure of FIG. 4B in the second position. Referring to FIG. 4A to FIG. 4B, FIG. 5, and FIG. 6, the first connector 120 of this embodiment includes a case 122 and a circuit board 124. The case 122 is disposed in the slot 110a of the body 110, and the case 122 has a pierced portion 122a adjacent to the opening 110b of the slot 110a (see FIG. 3). When the holder 130 is in the first position, the supporting surface 132a of the holder 130 is received in the pierced portion 122a. When the holder 130 is rotated from the first position to the second position, the supporting surface 132a of the holder 130 moves out of the slot 110a of the body 110 from the pierced portion 122a of the case 122 through the opening 110b of the slot 110a. The circuit board 124 is disposed in the case 122 and includes a plurality of terminals 124a exposed by the pierced portion 122a of the case 122.

More specifically, the case 122 includes a first plate 122b and a second plate 122c. The circuit board 124 is disposed on the first plate 122b. The second plate 122c is bent across the circuit board 124 and connected with two opposite sides of the first plate 122b. A side edge of the first plate 122b protrudes with respect to a side edge of the second plate 122c, and the pierced portion 122a is located between the second plate 122c and the opening 110b of the slot 110a. When the holder 130 is in the second position, the supporting surface 132a of the holder 130 and a surface s of the second plate 122c are on the same plane p. More specifically, when the second connector 10 is inserted into the slot 110a of the body 110, the second connector 10 is substantially held between the first plate 122b and the second plate 122c, and a bottom of the second connector 10 is supported by the supporting surface 132a of the holder 130 and the surface s of the second plate 122c on the same plane p. Therefore, the second connector 10 is supported by the supporting surface 132a and the surface s respectively. Since a supporting area for supporting the second connector 10 is increased, the connector structure 120a achieves favorable support.

In addition, when the holder 130 is in the first position, an angle θ is formed between the supporting surface 132a of the holder 130 and the surface s of the second plate 122c, wherein the angle θ may be an acute angle, such as 45 degrees, for example. With the angle θ, when the second connector 10 presses the supporting surface 132a of the holder 130 in a direction D1, the holder 130 is easily driven from the first position to the second position since the supporting surface 132a is a slope with respect to the direction D1.

In conclusion of the above, according to the invention, the holder is rotated between two positions, so as to rotate the supporting surface of the holder outside the slot of the body in the second position for supporting a portion of the second connector. Accordingly, the connector structure provides a favorable holding force for holding the second connector and ensures the support. Thus, when the first connector and the second connector are connected with each other, the second connector is prevented from coming off the first connector, and poor contact between the two connectors and failure of electrical connection are avoided. Therefore, the electronic apparatus using the connector structure has favorable reliability. Moreover, when the holder is rotated inside the slot of the body, the outer edge of the holder matches the opening of the slot, such that the shapes of the connector structure and the body are integrated with each other. Accordingly, the electronic apparatus using the connector structure meets the demands for higher reliability and thinner size.

It will be apparent to those skilled in the art that various modifications and variations can be made to the disclosed embodiments without departing from the scope or spirit of the invention. In view of the foregoing, it is intended that the invention covers modifications and variations of this disclosure provided that they fall within the scope of the following claims and their equivalents.

What is claimed is:

1. A connector structure, adapted for an electronic apparatus comprising a slot, the connector structure comprising:
a first connector disposed in the slot; and
a holder pivoted to an internal wall of the slot to be rotated between a first position and a second position, wherein the holder comprises a supporting surface, and when a second connector is inserted into the slot to connect the first connector, the second connector presses the supporting surface to drive the holder to rotate from the first position to the second position, such that a portion of the second connector is supported on the supporting surface.

2. The connector structure according to claim 1, wherein when the holder is in the first position, the supporting surface is located inside the slot; and when the holder is in the second position, the supporting surface is located outside the slot.

3. The connector structure according to claim 1, wherein the first connector comprises:
a case disposed in the slot and comprising a pierced portion adjacent to an opening of the slot, wherein when the holder is in the first position, the supporting surface is received in the pierced portion; and when the holder is rotated from the first position to the second position, the supporting surface moves out of the slot from the pierced portion through the opening of the slot; and
a circuit board disposed in the case and comprising a plurality of terminals exposed by the pierced portion.

4. The connector structure according to claim 3, wherein the case comprises a first plate and a second plate, and the circuit board is disposed on the first plate, and the second plate is bent across the circuit board and connected with two opposite sides of the first plate, wherein when the holder is in the second position, the supporting surface of the holder and a surface of the second plate are on the same plane.

5. The connector structure according to claim 4, wherein when the holder is in the first position, the supporting surface and the surface of the second plate form an angle.

6. The connector structure according to claim 4, wherein the pierced portion is located between the second plate and the opening of the slot.

7. The connector structure according to claim 1, further comprising an elastic member connecting the holder and the internal wall of the slot, wherein the elastic member constantly drives the holder to the first position, so as to maintain the supporting surface in the slot.

8. An electronic apparatus, comprising:
a body comprising a slot;
a first connector disposed in the slot; and
a holder pivoted to an internal wall of the slot to be rotated between a first position and a second position, wherein the holder comprises a supporting surface, and when a second connector is inserted into the slot to connect the first connector, the second connector presses the supporting surface to drive the holder to rotate from the first position to the second position, such that a portion of the second connector is supported on the supporting surface.

9. The electronic apparatus according to claim 8, wherein when the holder is in the first position, the supporting surface is located inside the slot; and when the holder is in the second position, the supporting surface is located outside the slot.

10. The electronic apparatus according to claim 8, wherein the first connector comprises:
a case disposed in the slot and comprising a pierced portion adjacent to an opening of the slot, wherein when the holder is in the first position, the supporting surface is received in the pierced portion; and when the holder is rotated from the first position to the second position, the supporting surface moves out of the slot from the pierced portion through the opening of the slot; and
a circuit board disposed in the case and comprising a plurality of terminals exposed by the pierced portion.

11. The electronic apparatus according to claim 10, wherein the case comprises a first plate and a second plate, and the circuit board is disposed on the first plate, and the second plate is bent across the circuit board and connected with two opposite sides of the first plate, wherein when the holder is in the second position, the supporting surface of the holder and a surface of the second plate are on the same plane.

12. The electronic apparatus according to claim 11, wherein when the holder is in the first position, the supporting surface and the surface of the second plate form an angle.

13. The electronic apparatus according to claim 11, wherein the pierced portion is located between the second plate and the opening of the slot.

14. The electronic apparatus according to claim 8, further comprising an elastic member connecting the holder and the internal wall of the slot, wherein the elastic member constantly drives the holder to the first position, so as to maintain the supporting surface in the slot.
